(19) United States
(12) Patent Application Publication
(10) Pub. No.: US 2025/0018486 A1
(43) Pub. Date: Jan. 16, 2025

(54) SYSTEM AND METHOD OF THINNING WAFER SUBSTRATE

(71) Applicant: COMPTAKE TECHNOLOGY INC., NEW TAIPEI CITY (TW)

(72) Inventors: YAO-GUANG YANG, NEW TAIPEI CITY (TW); KUEN-CHIH LAN, NEW TAIPEI CITY (TW); ZHI WEN FAN, NEW TAIPEI CITY (TW); CHAO-CHANG CHEN, NEW TAIPEI CITY (TW)

(21) Appl. No.: 18/710,184

(22) PCT Filed: Nov. 15, 2022
(86) PCT No.: PCT/CN2022/131956

§ 371 Date: May 15, 2024

Related U.S. Application Data
(60) Provisional application No. 63/279,272, filed on Nov. 15, 2021.

(51) Int. Cl. B23H 5/08; B23H 5/10; B23H 11/00; H01L 21/02; H01L 21/66; H01L 21/67; H01L 21/683

(52) U.S. Cl. CPC B23H 5/08; B23H 5/10; B23H 11/003; H01L 21/02013; H01L 21/67034; H01L 21/67092; H01L 21/6838; H01L 22/26

(57) ABSTRACT

A wafer processing system (1) is provided. The system (1) includes a processing tool (10) comprising at least one grinding member (16) used to remove material from a wafer substrate (80). The system (1) also includes an electrolyte supply line (361) used to supply an electrolyte to the wafer substrate (80). The system (1) further includes a holding module (20) for holding the wafer substrate (80). The holding module (20) includes a conductive base (21) and a conductive porous member (22) positioned on the top surface of the conductive base (21). A vacuum source (53) fluidly communicated with fluid channel (214) formed in the conductive base (21) to create a vacuum to hold the wafer substrate (80) on the conductive porous member (22). In addition, the system (1) includes an actuator assembly for driving a rotation of the grinding member (16) and a rotation of the conductive base (21), and a power supply module (45) to apply an electric current to the grinding member (16) and to the conductive porous member (22) through the conductive base (21).

### PRIORITY CLAIM

This application is a 371 application of the International Patent Application No. PCT/CN2022/131956 filed 15 Nov. 2022, which claims the priority of U.S. Provisional Application No. 63/279,272, filed 15 Nov. 2021, the disclosures of which are hereby incorporated by reference herein in their entireties.

### FIELD OF THE INVENTION

Embodiments of present disclosure relate to a system and a method that are used in a semiconductor industry for thinning wafer substrate through electrochemical grinding technique.

### BACKGROUND

The semiconductor integrated circuit (IC) industry has experienced exponential growth. Technological advances in IC materials and design have produced generations of ICs where each generation has smaller and more complex circuits than the previous generation. Wafer scale three-dimensional (3D) integration is recognized as an emerging technology to increase the performance and functionality of ICs. Electronic components are built on two or more wafer substrates, which are then aligned, bonded, and diced into 3D ICs.

To decrease the overall thickness of a final product of the 3D ICs, a wafer thinning process is conducted before or after bonding. Wafer thinning, also known as wafer grinding, is a step in the fabrication of semiconductor devices during which wafer thickness is reduced to allow for stacking and high-density packaging of integrated circuits for compact electronic devices. In a conventional wafer thinning process, grinding members with different grit sizes are utilized to contact material of a substrate directly so as to remove material from the substrate by pure mechanical activity (i.e., no electrochemical activity occurs.) However, due to grinding damage and residual stresses, a wafer warping or a propagation of cracks present in the wafer will inevitably occur. In another alternative method, a CMP (chemical-mechanical polishing) process is performed after the completion of the conventional wafer thinning process. In order to address the issued in the conventional wafer thinning process, wafers processed by this method are thinned to a thickness, which is much greater than a desired thickness of the final product, by the conventional wafer thinning process, and then is subjected to the CMP process to make the thickness of the wafer have the final desire value. However, the material removal rate (MRR) of the CMP process is relative low, which greatly increases the process time and thus results in a poor throughput.

It would be desirable to develop methods of electrochemical removal that avoided some or all of the above-discussed problems.

### SUMMARY

One aspect of the present disclosure provides a wafer processing system. The system includes: a processing tool including at least one grinding member configured to remove material from a wafer substrate; at least one electrolyte supply line configured to supply an electrolyte to the wafer substrate; a holding module positioned below the processing tool and including: a conductive base, wherein at least one fluid channel extends from a top surface to a bottom surface of the conductive base; a conductive porous member positioned on the top surface of the conductive base; and a vacuum source fluidly communicated with the fluid channel of the conductive base to create a vacuum to hold the wafer substrate on the conductive porous member; an actuator assembly configured to drive at least one of a rotation of the grinding member and a rotation of the conductive base; and a power supply module configured to apply an electric current to the grinding member and to the conductive porous member through the conductive base.

In some embodiments, the system further includes a fluid conveying member configured to provide a fluid communication between the fluid channel of the conductive base and the vacuum source while the conductive base is rotated.

In some embodiments, the fluid conveying member includes: a stationary housing including a plurality gas outlets; and a rotation shaft positioned in the stationary housing and rotatable with the conductive base and the conductive porous member, wherein a conduit is formed within the rotation shaft and is with one end fluidly communicated with the fluid channel of the conductive base and with the other end fluidly communicated with the gas outlets.

In some embodiments, the system further includes: an electrode arranged around a rotation axis about which the conductive base rotates; and a plurality of electric contacts positioned between the electrode and the conductive base, wherein the electrode is kept stationary while the conductive base is rotated, and the electric current from the power supply module is applied to the conductive base via the electrode and the electric contacts.

In some embodiments, a top surface of the conductive base includes a plurality of protrusions, and the conductive porous member includes a plurality of grooves arranged relative to the protrusions.

In some embodiments, the conductive porous member is made of material selected from the group consisting of stainless steel, titanium alloy, and tungsten carbide.

In some embodiments, the system further includes: an exhaust piping fluidly communicated with the fluid channel of the conductive base, wherein the vacuum source is connected to the exhaust piping; an electrolyte reservoir configured to store the electrolyte; a bypass piping fluidly communicated between the exhaust piping and the electrolyte reservoir; and a liquid regulating module operative in an operating mode and a rest mode, wherein in the operating mode, the liquid regulating module guides the fluid from the fluid channel to an ambient via the exhaust piping, and in the rest mode, the liquid regulating module guides the fluid from the fluid channel to the electrolyte reservoir via the exhaust piping and the bypass piping.

In some embodiments, the system further includes: a supply piping fluidly communicated between the electrolyte reservoir and the at least one electrolyte supply line; and a filtration module connected to the supply piping; wherein the electrolyte from the electrolyte reservoir is circulated back to the at least one electrolyte supply line via the filtration module.

In some embodiments, the processing tool further includes a rotation head defining a recess at a bottom surface thereof, and the grinding member is positioned on the bottom surface of the rotation head and surrounds the recess, wherein the at least one electrolyte supply line includes a first electrolyte supply line configured to discharge the electrolyte into the recess.

In some embodiments, the at least one electrolyte supply line further includes a second electrolyte supply line configured to discharge the electrolyte to a contact point between the grinding member and the wafer substrate.

In another aspect of the present invention, a wafer processing system is provided. The system includes: a processing tool including: a rotation shaft; a rotation head fixed to a lower end of the rotation shaft and defining a recess at a bottom surface of the rotation head; a grinding member positioned on the bottom surface of the rotation head and surrounding the recess; a first electrode surrounding the rotation shaft and electrically connected to the rotation head; and a fluid supply line formed within the rotation shaft and the rotation head and configured to supply an electrolyte to the recess; a holding module configured to hold a wafer substrate and including a second electrode; an actuator assembly configured to drive a rotation of the processing tool; and a power supply module configured to apply an electric current to the first and the second electrodes.

In some embodiments, the grinding member is made of material consisting conductive metallic powder and non-conductive abrasive particles.

In some embodiments, the head portion includes: a disc, wherein a plurality of grooves are formed at a lower surface of the disc portion, and an end of the fluid line is formed on the disc; a flange extends downward from a peripheral edge of the disc, wherein the recess is defined by the disc and the flange; and a fluid guiding plate having a plurality of holes formed thereon for allowing electrolyte from the fluid line passing through.

In some embodiments, the recess of the rotation head is surrounded by a flange that downward extends to the bottom surface of the rotation head, and the flange includes a plurality of notches that are fluidly communicated with the recess.

In some embodiments, the processing tool further includes a transducer connected to the fluid supply line to generate an ultrasonic energy to the electrolyte.

Still another aspect of the present disclosure, a wafer processing method is provided. The method includes loading a wafer substrate on a holding module; contacting a grinding member with a surface of the wafer substrate, wherein the grinding member is arranged around a recess; applying an electric current to the wafer substrate and the grinding member and supplying an electrolyte into the recess so as to form an oxide layer on the surface of the wafer substrate; performing a grinding process by rotating the grinding member; and adjusting the movement of the grinding member or the supply of the electrolyte when a monitored parameter that is associated with thickness of the oxide layer is not within a range of a preset value.

In some embodiments, the monitored parameter is a rotation speed of the grinding member, and when the rotation speed of the grinding member is lower than a preset value, a flow rate of the electrolyte is increased.

In some embodiments, the monitored parameter is a pressure applied on the grinding member, and when the pressure is greater than a preset value, a flow rate of the electrolyte is increased or a height of the grinding member relative to the wafer substrate is decreased.

In some embodiments, the monitored parameter is an electric potential difference between the grinding member and the wafer substrate, and when the electric potential difference is outside a range of value, a moving speed of the grinding member is changed.

In some embodiments, the method further includes: stopping the grinding process when a flow rate of the electrolyte, a conductivity of the electrolyte, or a pH value of the electrolyte is outside a range of value; and replacing the electrolyte after the grinding process is stopped.

The above summary is not intended to describe each illustrated embodiment or every implementation of the present disclosure.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 shows a block diagram of a wafer processing system, in accordance with one or more embodiments of the present disclosure.

FIG. 2 shows a schematic cross-sectional view of a wafer processing system, in accordance with one or more embodiments of the present disclosure.

FIG. 3A shows a schematic cross-sectional view of partial elements of a processing tool, in accordance with one or more embodiments of the present disclosure.

FIG. 3B shows a bottom view of a dish of the processing tool of FIG. 3A.

FIG. 4A shows a schematic cross-sectional view of partial elements of a processing tool, in accordance with one or more embodiments of the present disclosure.

FIG. 4B shows a bottom view of a dish of the processing tool of FIG. 4A.

FIG. 5 shows a schematic cross-sectional view of partial elements of a processing tool, in accordance with one or more embodiments of the present disclosure.

FIG. 6 shows a schematic cross-sectional view of partial elements of a holding module, in accordance with one or more embodiments of the present disclosure.

FIG. 7 shows a top view of a conductive support of the holding module of FIG. 6.

FIG. 8 shows a schematic view of a wafer processing system, in accordance with one or more embodiments of the present disclosure.

FIG. 9 shows a schematic view of a flow stabilizing device, in accordance with one or more embodiments of the present disclosure.

FIG. 10 shows a schematic view of an electrolyte supply line, in accordance with one or more embodiments of the present disclosure.

FIG. 11 shows a flow chart illustrating a method of fabricating a wafer substrate, in accordance with various aspects of one or more embodiments of the present disclosure.

FIG. 12 shows a flow chart illustrating a method of thinning a wafer substrate, in accordance with various aspects of one or more embodiments of the present disclosure.

FIG. 13 shows a schematic view illustrating one stage of a method of performing a grinding process at which an oxide layer is adequately formed at a surface of the wafer substrate during a grinding process, in accordance with one or more embodiments of the present disclosure.

FIG. 14 shows a schematic view illustrating one stage of a method of performing a grinding process at which an abnormal is detected during the grinding process, in accordance with one or more embodiments of the present disclosure.

FIG. 15 is a waveform chart showing an example of current provided to a wafer substrate in a maintenance process, in accordance with one or more embodiments of the present disclosure.

### DETAILED DESCRIPTION

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

The terminology used in this specification is intended to describe particular embodiments and is not intended to be limiting. The terms “a,” “an,” and “the” include the plural forms as well, unless clearly indicated otherwise. The terms “comprises,” and/or “includes,” when used in this specification, specify the presence of the stated features, integers, steps, operations, elements, and/or components, but do not preclude the presence or addition of one or more other features, integers, steps, operations, elements, and/or components.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

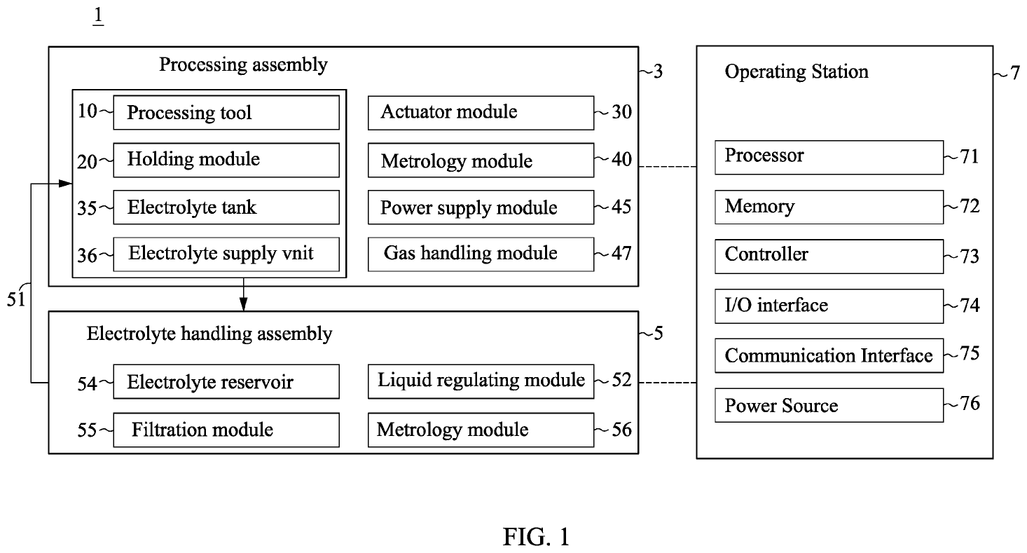

FIG. 1 shows a block diagram of a wafer processing system 1, in accordance with one or more embodiments of the present disclosure. In accordance with some embodiments, the wafer processing system 1 is configured to perform a grinding process over a wafer substrate by electrochemical grinding technique and includes a processing assembly 3, an electrolyte handling assembly 5 and an operating station 7.

The processing assembly 3 is where fabrication takes place and contains a processing tool 10, a holding module 20, an actuator module 30, an electrolyte tank 35, at least one electrolyte supply line, such as electrolyte supply lines 361 and 365, a metrology module 40, a power supply module 45 and a gas handling module 47. The electrolyte handling assembly 5 is used to process the electrolyte which is used in or to be supplied to the processing assembly 3 and includes a piping unit 51, a liquid regulating module 52, and an electrolyte reservoir 54, a filtration module 55, and a metrology module 56. The operating station 7 is used to control and monitor the operation of the processing assembly 3 and the electrolyte handling assembly 5. The operating station 7 may comprise a processor 71, a memory 72, a controller 73, an input/output interface 74 (hereinafter “I/O interface”), a communications interface 75, and a power source 76.

The wafer substrate to be processed in the present disclosure may be made of silicon or other semiconductor materials. Alternatively or additionally, the wafer substrate may include other elementary semiconductor materials such as germanium (Ge). In some embodiments, the wafer substrate is made of a compound semiconductor such as silicon carbide (SiC), gallium arsenic (GaAs), indium arsenide (InAs), or indium phosphide (InP). In some embodiments, the wafer substrate is made of an alloy semiconductor such as silicon germanium (SiGe), silicon germanium carbide (SiGeC), gallium arsenic phosphide (GaAsP), or gallium indium phosphide (GaInP). In some embodiments, the wafer substrate includes an epitaxial layer. For example, the wafer substrate has an epitaxial layer overlying a bulk semiconductor. In some other embodiments, the wafer substrate may be a silicon-on-insulator (SOI) or a germanium-on-insulator (GOI) substrate. In one particular example, the wafer substrate to be processed by the wafer processing system 1 is a silicon wafer having a diameter of 6 inches, 8 inches, 12 inches, or 14 inches, or is workpiece made of conductive single-crystal silicon carbide having a diameter of 4 inches or 6 inches.

The wafer substrate may have various device elements. Examples of device elements that are formed in the wafer substrate include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, a shallow trench isolation (STI) layer, an inter-layer dielectric (ILD), or an inter-metal dielectric layer covers the device elements formed on the wafer substrate. Alternatively, the wafer substrate to be processed may be a blank wafer.

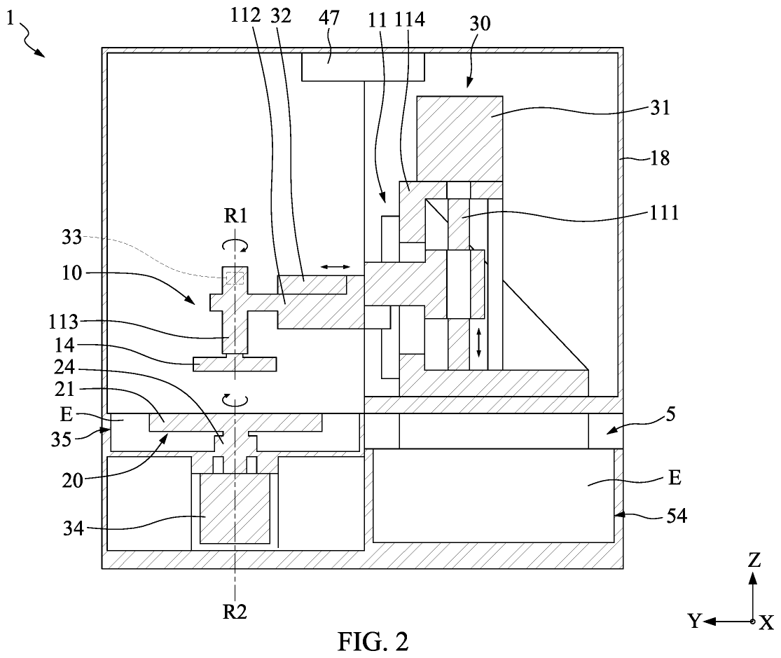

FIG. 2 shows a schematic cross-sectional view of the wafer processing system 1, in accordance with one or more embodiments of the present disclosure. In some embodiments, the processing tool 10 includes a platform 11 and a rotation head 14. The platform 11 is used to support the rotation head 14 and the actuator module 30 which drives a motion of the rotation head 14. As shown in FIG. 2, in one exemplary embodiment, the platform 11 includes a frame 114, a horizontal arm portion 112 and a vertical arm portion 113. A first upper actuator 31 of the actuator module 30 is fixed on a top of a frame 114, and a ball screw 111 is connected to the first upper actuator 31 and extends within the frame 114 for driving a movement of the horizontal arm portion 112 in a vertical direction (Z-axis direction). In addition, a second upper actuator 32 of the actuator module 30 is fixed on the horizontal arm portion 112 to drive a movement of the vertical arm portion 113 in horizontal directions (X-axis and Y-axis directions). Furthermore, a third upper actuator 33 of the actuator module 30 is fixed on the vertical arm portion 113 to drive a rotation of the rotation head 14 about a rotation axis R1 which is parallel to Z-axis.

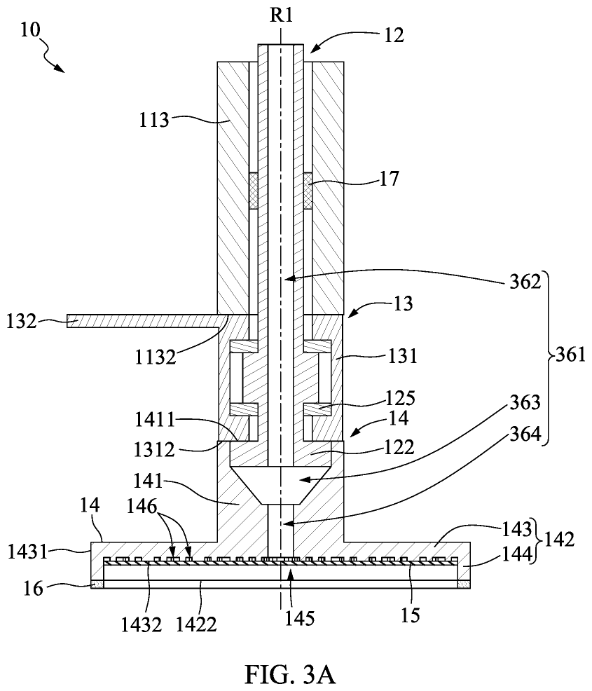

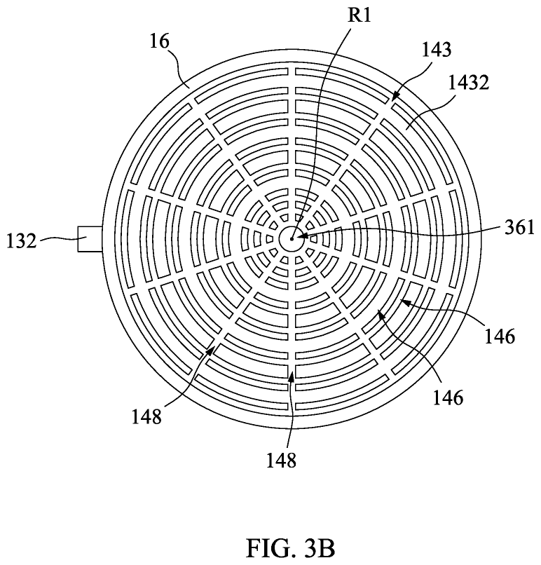

FIG. 3A shows a schematic cross-sectional view of partial elements of the processing tool 10, in accordance with one or more embodiments of the present disclosure. In some embodiments, the processing tool 10 further includes a rotation shaft 12, an electrode 13, a distribution plate 15, a grinding member 16, and a transducer 17. The vertical arm portion 113 is a hollow structure, and the rotation shaft 12 extends therein with its upper end connected to the third upper actuator 33 (FIG. 2) and with its lower end stretching out of an opening formed on a bottom surface 1132 of the vertical arm portion 113. The electrode 13 is fixed to the bottom surface 1132 of the vertical arm portion 113. The electrode has a ring-shaped body 131 and a connecting portion 132. The lower portion of the rotation shaft 12 passes through a center of the ring-shaped body 131 and connected to an inner surface of the ring-shaped body 131 through a number of bearing 125. With the bearing 125, the electrode 13 and the vertical arm portion 113 are kept stationary while the rotation shaft 12 is rotated. The connecting portion 132 extends radially from the outer wall of the ring-shaped body 131 and is electrically connected to the power supply module 45 (FIG. 1).

The rotation head 14 is positioned below and is electrically connected to the ring-shaped body 131 through an electric contact, such as brush spring. In one exemplary embodiment, the rotation head 14 includes a neck portion 141 and an expanded portion 142. The neck portion 141 and the expanded portion 142 are integrally formed with a conductive material, such as an alloy of cooper and tin, alloy of copper and nickel, alloy of coper and zinc, or the like. The lower end 122 of the rotation shaft 12 is fixed to the neck portion 141, and the expanded portion 142 is connected to a bottom side of the neck portion 141. The expanded portion 142 is connected to the neck portion 141 by a disc 143. The disc 143 has a circular shape and has a diameter which is greater than that of the neck portion 141. A flange 144 of the expanded portion 142 extends from a lower surface 1432 of the disc 143, and terminates at a bottom surface 1422 of the rotation head 14. The flange 144 is immediately adjacent to and extends along a peripheral edge 1431 of the disc 143, and thus a circular recess 145 is defined at the bottom surface 1422 of the rotation head 14.

The grinding member 16 or abrasive member configured to remove material from a wafer substrate is connected to the bottom surface 1422 of the rotation head 14. The grinding member 16 has a ring shape and surrounds the recess 145. In one exemplary embodiment, a cross section of the grinding member 16 taken along a direction perpendicular to the rotation axis R1 is the same as that of the flange 144 taken along the same direction. However, it will be appreciated that many variations and modifications can be made to embodiments of the disclosure. In some embodiments, as observed from a bottom side, the width of the grinding member 16 may be greater or less than that of the flange 144. In some embodiments, the grinding member 16 is conductive and is made of material consisting conductive metallic powder and non-conductive abrasive particles. The conductive metallic powder comprises powered cooper or powered tin, and the non-conductive abrasive particles comprises diamond, cubic zirconia or silicon carbide. In some embodiments, a ratio of a weight of the conductive metallic powder and a weight of the non-conductive abrasive particles is in a range of from about 2 to about 1 (i.e., 1:(1˜0.5)).

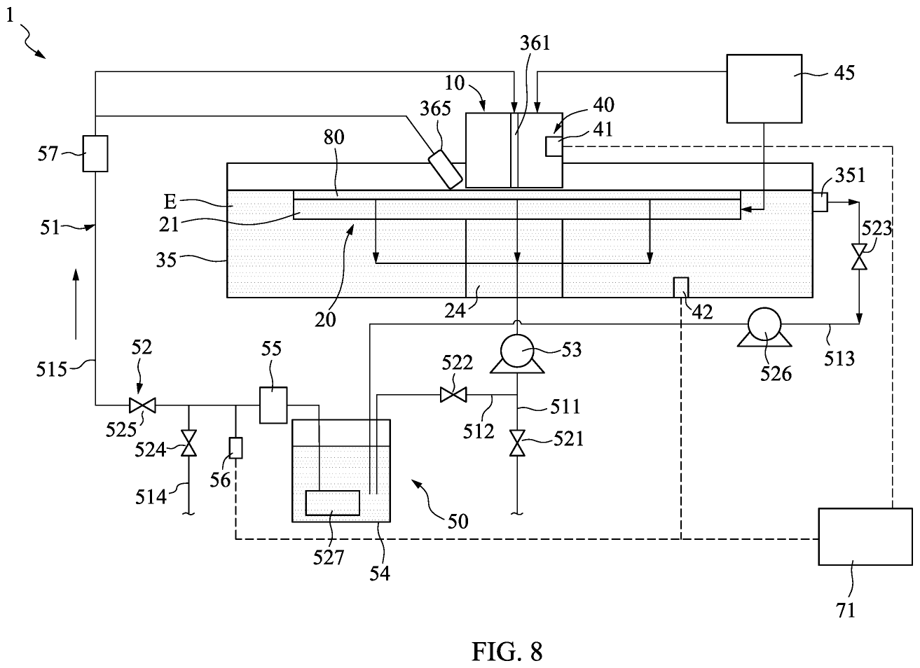

In some embodiments, electrolyte for facilitating an oxidation reaction and/or reduction reaction of the wafer substrate to be processed is supplied into the recess 145 through the electrolyte supply line 361 which is formed within the processing tool 10. For example, as shown in FIG. 3A, the electrolyte supply line 361 includes an upstream segment 362, an intermediate segment 363, and a downstream segment 364 sequentially arranged along the rotation axis R1. The upstream segment 362 is formed within the rotation shaft 12, and the intermediate segment 363 and the downstream segment 364 are formed within the rotation head 14. The intermediate segment 363 may be tapped away from the upper surface 1411 of the neck portion 141 so as to stabilize the flow of electrolyte. The downstream segment 364 is connected to a lower end of the intermediate segment 363. The lower end of the downstream segment 364 is located at a center of the disc 143. In operation, electrolyte from an electrolyte reservoir (FIG. 8) is supplied to the electrolyte supply line 361 by a supplying piping 515 (FIG. 8) and then is injected into the recess 145 through the upstream segment 362, the intermediate segment 363, and the downstream segment 364. A distribution plate 15 with multiple through hole (not shown) is placed below the lower end of the downstream segment 364 to make the electrolyte flow into the recess 145 evenly. Method for supplying the electrolyte will be describe in more detailed with reference to the embodiment shown in FIG. 8.

In some embodiments, to further improve the flow field of the electrolyte in the recess, the lower surface 1432 is patterned to form a number of features to guide the electrolyte to evenly flow through entire lower surface 1432 of the disc 143 before entering the recess 145. For example, as shown in FIG. 3B, a number of first grooves 146 are arranged concentrically around the rotation axis R1 and formed at the lower surface 1432 of the disc 143. In addition, a number of second grooves 148 extending along a radial direction of the lower surface 1432 are arranged at the lower surface 1432 of the disc 143 with a constant space. The fluid from the electrolyte supply line 361 flows through the first and second grooves 146 and 148 before passing through the distribution plate 15.

The transducer 17 is configured to excite the flow of electrolyte in the electrolyte supply line 361. In some embodiments, the transducer 17 is located in the vertical arm portion 113 and surrounds the rotation shaft 12. The transducer 17 may generate an ultrasonic energy so as to generate hydroxyl radicals, by electro-Fenton process, in the electrolyte when the electrolyte flows through the electrolyte supply line 361. With more hydroxyl radicals in the electrolyte, oxidation reaction or reduction reaction of the wafer substrate may be triggered easier without the application of electric current with a large voltage to the grinding member, which may adversely prolong the processing time of the grinding process.

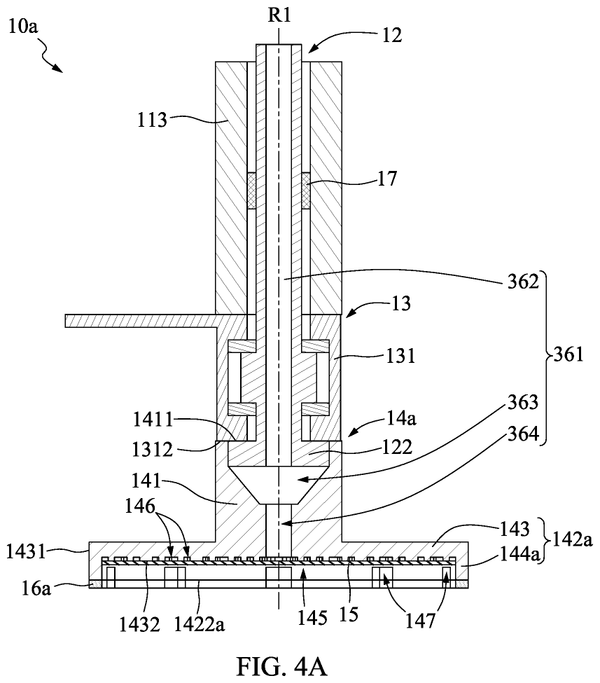

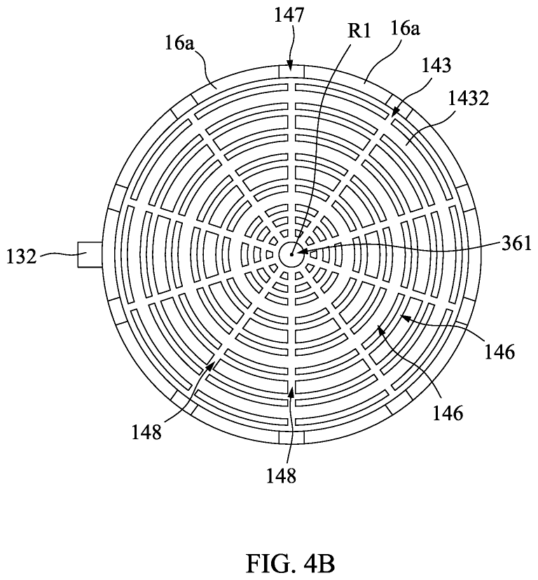

FIG. 4A shows a schematic cross-sectional view of partial elements of a processing tool 10a, in accordance with one or more embodiments of the present disclosure. The components in FIG. 4A that use the same reference numerals as the components of FIG. 3A refer to the same components or equivalent components thereof. For the sake of brevity, it will not be repeated here. Differences between the processing tool 10 and the processing tool 10a include the rotation head 14 being replaced with a rotation head 14a, and the grinding member 16 being replaced with a number of grinding members 16a. The rotation head 14a includes a neck portion 141 and an expanded portion 142a. A number of notches 147 are formed at the flange 144a of the expanded portion 142a. As shown in FIG. 4B, the notches 147 are spaced in a constant space in a circumferential direction of the disc 143. The grinding members 16a each has an arc-shaped cross-section is attached to the bottom surface of the flange 144a. The grinding members 16a may be formed with the same material of the grinding member 16 of FIG. 3A.

In operation, electrolyte supplied from an electrolyte supply line 365 (FIG. 8) which is located at outside of the recess 145 may enter the recess 145 through the notches 147 and the gaps between two neighboring grinding members 16a to facilitate the grinding process. In cases where notches are formed at the rotation head 14a of the processing tool 10a, the electrolyte supply line 361 that formed within the processing tool 10a and the distribution plate 15 may be omitted.

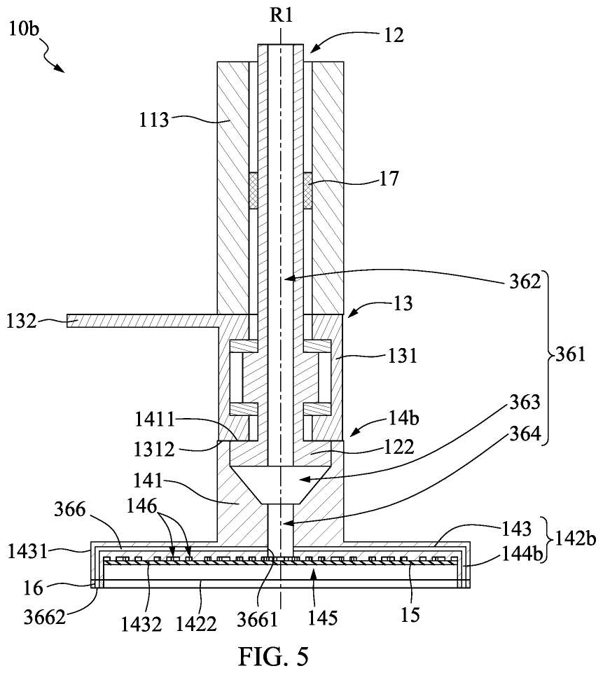

FIG. 5 shows a schematic cross-sectional view of partial elements of a processing tool 10b, in accordance with one or more embodiments of the present disclosure. The components in FIG. 5 that use the same reference numerals as the components of FIG. 3A refer to the same components or equivalent components thereof. For the sake of brevity, it will not be repeated here. Differences between the processing tool 10 and the processing tool 10b include the rotation head 14 being replaced with a rotation head 14b. The rotation head 14b includes a neck portion 141 and an expanded portion 142b.

An inner flowing path 366 which is configured to deliver the electrolyte to a bottom surface of the grinding member 16b is formed within the expanded portion 142b. A first end 3661 of the inner flowing path 366 is connected to the downstream segment 364 and a second end 3662 is formed at the bottom surface of the grinding member 16b. The bottom surface of the grinding member 16b serve as a primary functional surface to remove material from the wafer substrate. In operation, a portion of electrolyte from the electrolyte supply line 361 may flow into the inner flowing path 366 and be directly supplied to a surface of the wafer substrate that contacts with the grinding member 16b. With the electrolyte from the inner flowing path 366, the electrolyte is stably and continuously supplied into a gap between the bottom surface of the grinding member 16b and the surface of the wafer substrate. Therefore, a concern that an unstable oxidation rate of the wafer substrate during a grinding process may be mitigated.

Referring back to FIG. 2, the electrolyte tank 35 is configured to collect the electrolyte and the residuals produced during the grinding process. The electrolyte tank 35 may define a volume in which the holding module 20 is positioned. In addition, the electrolyte tank 35 has an open upper end to permit the insertion of the processing tool 10 into the electrolyte tank 35. In some embodiments, the wafer processing system 1 further includes a protective housing 18. The processing tool 10, the holding module 20, and the electrolyte tank 35 are accommodated in a protective housing 18. A gas handling module 47 may be positioned on a top side of the protective housing 18 to exhaust particles, volatile gas, or splashing electrolyte from the protective housing 18. A negative pressure environment can be established in the protective housing 18 by the gas handling module 47.

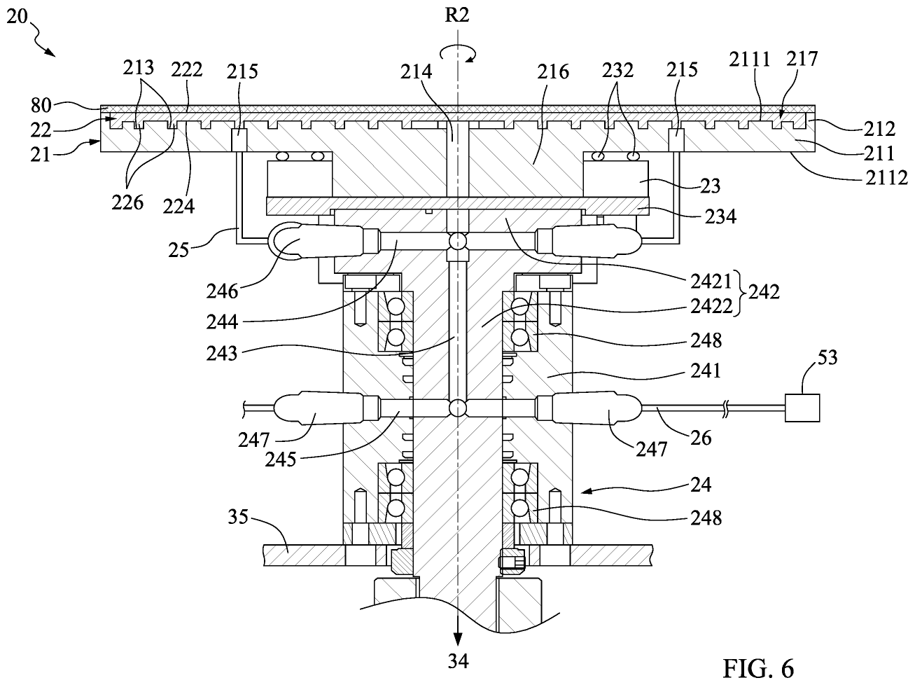

FIG. 6 shows a schematic cross-sectional view of partial elements of a holding module 20, in accordance with one or more embodiments of the present disclosure. The holding module 20 is configured to hold, position, and rotate a wafer substrate to be processed. In some embodiments, the holding module 20 includes a conductive support 21, a conductive porous member 22, and an electrode 23, and a fluid conveying member 24. The conductive support 21 allows a transmission of electric current from the electrode 23 to the conductive porous member 22. In some embodiments, the conductive support 21 includes a base 211, a flange 212, and a lower portion 216. The base 211 and the flange 212, and the lower portion 216 may be integrally formed with a conductive material, such as an alloy of cooper and tin. The base 211 is a circular plate, and the flange 212 is connected to a top surface 2111 of the base 211 and extends from a peripheral edge of the base 211 to form an accommodation space 217. The conductive porous member 22 is layered on the top surface 2111 of the base 211 and located within the accommodation space 217. The lower portion 216 is connected to a bottom surface 2112 of the base 211 and extends downward. The electrode 23 surrounds the lower portion 216 and electrically connected to the bottom surface 2112 of the base 211 through an electric contact 232, such as brush spring. Power from the power supply module 45 (FIG. 1) is provided to the conductive support 21 through the electrode 23. The electrode 23 is a stationary part when the holding module 20 is rotated.

In some embodiments, the conductive porous member 22 is formed on the conductive support 21 through sintering process by placing conductive power, such as silicon carbide (SiC), into the accommodation space 217 and compacting the powder to form the shape of the conductive support 21. In some embodiments, metallic power may be mixed into the silicon carbide. However, the present invention is not limited to the embodiment. In one alternative embodiment, no metallic power is added in the conductive porous member 22, and the conductive porous member is made by pure silicon carbide. Addition of metallic power will advantagely increase the electrical conductivity but may decrease the porosity of conductive porous member 22. In some embodiments, the porosity of the conductive porous member 22 may be in a range of 10% to 40%. A lower porosity of the conductive porous member 22 results in an improvement of flatness of the ultra-thin wafer substrate while the wafer substrate is fixed on the conductive porous member 22 by a vacuum force. In one exemplary embodiment, the metallic power is made of material, which had high conductivity, selected from the group consisting of stainless steel, titanium alloy, and tungsten carbide. The conductivity (a) of the conductive porous member 22 may be in a range of 10⁻³˜10³ (S/cm).

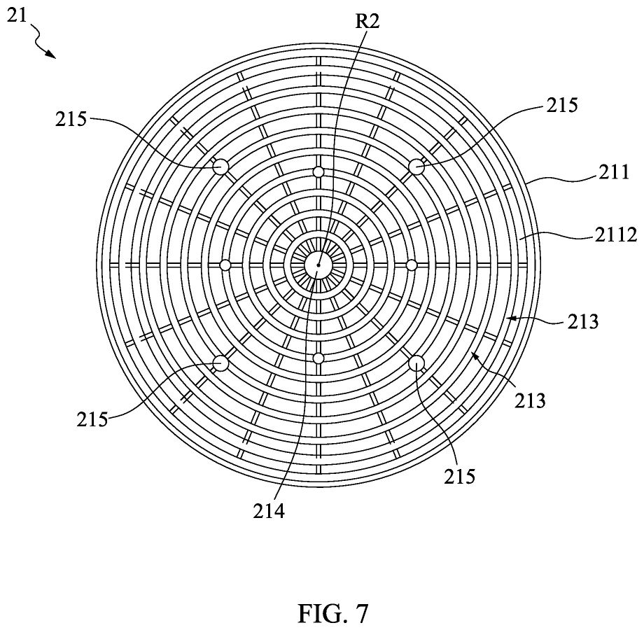

In some embodiments, the top surface 2111 of the base 211 is patterned to form a number of features so as to increase the contacting area between the base 211 and the conductive porous member 22 thereby improving the transmission of the electric current from the conductive support 21 to the conductive porous member 22. For example, as shown in FIG. 7, a number of grooves 213 are arranged concentrically around the rotation axis R2 and formed at the top surface 2111 of the base 211. In cases where the conductive porous member 22 is made by sintering process as mentioned above, the conductive porous member 22 have a shape which is conformal with the top surface 2111 of the base 211 which results in the formation of multiple protrusions formed on the bottom surface 224 of the conductive porous member 22. In addition, the top surface 222 of the conductive porous member 22 flash with the top free end of the flange 212. Therefore, the top surface 222 of the conductive porous member 22 and the top free end of the flange 212 cooperatively form a support surface to support the wafer substrate 80 during the grinding process.

In some embodiments, the wafer substrate 80 to be held by the holding module 20 is made of diamagnetic materials and will not be attracted by a magnetic field. Therefore, in order to stably hold the wafer substrate 80, the wafer substrate 80 is fixed on the holding module 20 through vacuum force. To generate such vacuum force, a number of fluid channels are formed inside the base 211 to allow fluid from the supporting surface to be exhausted. For example, the base 211 includes a central fluid channel 214 and a number of peripheral fluid channels 215. The central fluid channel 214 and the peripheral fluid channels 215 each penetrates the base 211 and connected between the top surface 2111 and the bottom surface 2112 of the base 211. As shown in FIG. 7, the central fluid channel 214 is formed relative to the rotation axis R2, and the peripheral fluid channels 215 are arranged circumferentially on the base 211. In some other embodiments, the peripheral fluid channels 215 do not pass through the bottom surface 2112 of the base 211, but each extends horizontally and inwardly to connect the central fluid channel 214. The liquid from the peripheral fluid channels 215 diverges in the central fluid channel 214 first and then is delivered to the vacuum source via the fluid conveying member 24.

The fluid conveying member 24 is configured to provide a fluid communication between the fluid channel, such as central fluid channel 214 and peripheral fluid channels 215, of the base 211 and a vacuum source while the base 211 is rotated. In some embodiments, the fluid conveying member 24 includes a stationary housing 241 and a rotation shaft 242. The rotation shaft 242 extends axially inside the stationary housing 241 and connected to the inner wall of the stationary housing 241 through multiple bearings 248. A bottom end of the rotation shaft 242 is connected to a lower actuator 34 of the actuator module 30. The lower actuator 34 is configured to drive the rotations of the rotation shaft 242 and may be positioned below the electrolyte tank 35.

In some embodiments, the rotation shaft 242 has a T-shaped cross-section and includes a head portion 2421 and an axial portion 2422. The head portion 2421 is connected the upper end of the axial portion 2422 and has a diameter that is greater than a diameter of the axial portion 2422. The head portion 2421 is fixed to the lower portion 216 of the conductive support 21. An insulator 234 may be placed between the head portion 2421 and the lower portion 216 to insulate the fluid conveying member 24 from the conductive support 21.

An axial conduit 243 extends from the top surface of the head portion 2421 along the rotation axis R2 for a predetermined distance. The axial conduit 243 is fluidly connected to the central fluid channel 214. A number of upper lateral conduits 244 are radially extends in the head portion 2421. Each of the upper lateral conduits 244 includes an inner end connected to the axial conduit 243 and an outer end connected with an inlet port 246 formed at the lateral surface of the head portion 2421. The inlet ports 246 are fluidly connected to the peripheral fluid channel 215 through multiple connection lines 25. In addition, a number of lower lateral conduits 245 are radially extends in the axial portion 2422. Each of the lower lateral conduits 245 includes an inner end connected to a lower end of the axial conduit 243 and an outer end connected with an outlet port 247 formed at the lateral surface of the stationary housing 241. The outlet ports 247 are fluidly connected to the vacuum pump 53.

Through the fluid conveying member 24, fluid is allowed to be delivered from the supporting surface on which the wafer substrate 80 is placed to a vacuum source, such as vacuum pump 53, to expel the gas and/or liquid from the supporting surface even if the conductive support 21 is rotated. Specifically, when a vacuum is created by the vacuum pump 53, the fluid from the central fluid channel 214 is driven to flow through the axial conduit 243, the lower lateral conduits 245, and the outlet ports 247 sequentially and leave the holding module 20, and the fluid from the peripheral fluid channels 215 is driven to flow through the connection lines 25, the inlet ports 246, the upper lateral conduits 244, the axial conduit 243, the lower lateral conduits 245, and the outlet ports 247 sequentially and leave the holding module 20.

FIG. 8 shows a schematic view of the wafer processing system 1, in accordance with one or more embodiments of the present disclosure. The piping unit 51 is used to deliver liquid in the wafer processing system 1 and includes an exhaust piping 511, a bypass piping 512, a recycling piping 513, a drain piping 514, and a supply piping 515. The exhaust piping 511 is connected to the holding module 20 and is used to deliver gas exhausted from the holding module 20 in an operating mode. The bypass piping 512 is connected to the exhaust piping 511 and is used to deliver gas and electrolyte from the holding module 20 in a rest mode. The operating mode refers to a status of the holding module 20 in which the wafer substrate 80 is positioned thereon. The rest mode refers to a status of the holding module 20 in which the wafer substrate 80 is removed from the supporting surface. The recycling piping 513 is used to deliver the electrolyte from an outlet port 351 of the electrolyte tank 35 to the electrolyte reservoir 54. The supply piping 515 is used to deliver the electrolyte from the electrolyte reservoir 54 to the electrolyte supply lines 361 and 365. The drain piping 514 is used to drain the waste electrolyte from the supply piping 515.

The liquid regulating module 52 is used to regulate the flow of the electrolyte or gas in the piping unit 51 in response to the signal from the controller 73 (FIG. 1) and includes multiple valves 521, 522, 523, 524, 525, a pump 526, and a submerged pump 527. The valve 521, the valve 522, the valve 523, the valve 524, and the valve 525 are respectively connected to the exhaust piping 511, the bypass piping 512, the recycling piping 513, the drain piping 514, and the supply piping 515 to control the flow in the piping. The pump 526 is used to actuate the flow in the recycling piping 513, and the submerged pump 527 is positioned in the electrolyte reservoir 54 to actuate the flow in the supply piping 515. In the operating mode, since the conductive porous member 22 is covered by the wafer substrate 80, no electrolyte will enter the exhaust piping 511, the controller 73 shuts off the valve 522 while keeps the valve 521 on so as to exhaust gas from the conductive support 21 to the ambient. In the rest mode, since the conductive porous member 22 is uncovered by the wafer substrate 80, electrolyte may enter the exhaust piping 511, the controller 73 shuts off the valve 521 while keeps the valve 522 on so as to expelled liquid and gas from the conductive support 21 to the electrolyte reservoir 54.

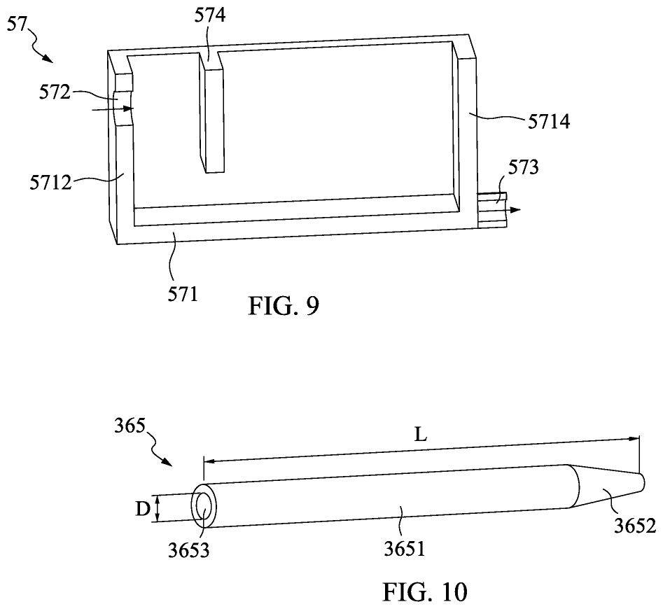

FIG. 9 shows a schematic view of a flow stabilizing device 57, in accordance with one or more embodiments of the present disclosure. In some embodiments, the liquid regulating module 52 may further includes a flow stabilizing device 57. The flow stabilizing device 57 includes a housing 571 having two opposite side walls 5712 and 5714. An inlet 572 is formed on the side wall 5712, and an outlet is formed on the side wall 5714. A blocking member 574 is positioned in the housing 571 and faces the inlet 572. The liquid regulating module 52 serves as a buffer tank to convert the flow from the electrolyte reservoir 54 to become steady flow before it enters the electrolyte supply lines 361 and 365.

FIG. 10 shows a schematic view of the electrolyte supplying line 365, in accordance with one or more embodiments of the present disclosure. In some embodiments, the electrolyte supply line 365 includes an elongated body 3651 and a nozzle 3652. An end opening 3653 of the elongated body 3651 is connected to the supply piping 515 to receive the electrolyte from the supply piping 515. The nozzle 3652 is connected to an end of the elongated body 3651 that is opposite to the end opening 3653. A length L of the electrolyte supply line 365 may be 10 times greater than a diameter D of the end opening 3653 to promote laminar flow. The elongated body 3651 may be made with flexible element so as to adjust dispensing angle of the electrolyte while dispensing the electrolyte to the wafer substrate.

Referring back to FIG. 8, the metrology modules 40 and 56 are configured to monitor at least one parameter in the wafer processing system 1 in real-time. In one embodiment, the metrology module 40 is positioned in the processing assembly 3 and can provide real-time monitoring of environmental parameters of the processing assembly 3. For example, the metrology module 40 includes a first sensor 41 positioned on the processing tool 10 and a second sensor 42 positioned in the electrolyte tank 35. The first sensor 41 may be used to detect parameters including a rotation speed of the rotation head 14 of the processing tool 10, a compression pressure applied on the rotation head 14 of the processing tool 10, an electric potential difference between the grinding member 16 of the processing tool 10 and the wafer substrate 80. The second sensor 42 may be used to detect parameters including a flow rate of the electrolyte, a pH value of the electrolyte, a conductivity of the electrolyte. The metrology module 56 is positioned in the electrolyte handling assembly 5 and can provide real-time monitoring of environmental parameters of the electrolyte handling assembly 5. For example, metrology module 56 is connected at a downstream of the filtration module 55 to detect a concentration of contamination in the electrolyte. The measurement results produced by the metrology modules 40 and 56 are transmitted to the processor 71.

Referring back to FIG. 1, the processor 71 may comprise any processing circuitry operative to process the measurement data generated by the metrology modules 40 and 56 to determine whether an abnormal occur. In various aspects, the processor 71 may be implemented as a general purpose processor, a chip multiprocessor (CMP), a dedicated processor, an embedded processor, a digital signal processor (DSP), a network processor, an input/output (I/O) processor, a media access control (MAC) processor, a radio baseband processor, a co-processor, a microprocessor such as a complex instruction set computer (CISC) microprocessor, a reduced instruction set computing (RISC) microprocessor, and/or a very long instruction word (VLIW) microprocessor, or other processing device.

In some embodiments, the memory 72 may comprise any machine-readable or computer-readable media capable of storing data, including both volatile/non-volatile memory and removable/non-removable memory which is capable of storing one or more software programs. The software programs may contain, for example, applications, user data, device data, and/or configuration data, archival data relative to the environmental parameter or combinations therefore, to name only a few. The software programs may contain instructions executable by the various components of the operating station 7. For example, memory 72 may comprise read-only memory (ROM), random-access memory (RAM), dynamic RAM (DRAM), disk memory (e.g., floppy disk, hard drive, optical disk, magnetic disk), or card (e.g., magnetic card, optical card), or any other type of media suitable for storing information. In one embodiment, the memory 72 may contain an instruction set stored in any acceptable form of machine readable instructions. The instruction set may include a series of operations after an abnormality is found in the wafer processing system 1 based on the signals obtained by the metrology modules 40 and 56.

The controller 73 is configured to control one or more elements of the wafer processing system 1. In some embodiments, the controller 73 is configured to drive the rotation of the rotation head 14 of the processing tool 10, the rotation of the holding member, the flow of electrolyte in the piping unit 51. The controller 73 includes a control element, such as a microcontroller. The controller 73 issues control signals to the actuator module 30, the liquid regulating module 52, and the vacuum pump 53 in response to a command from the processor 71.

In some embodiments, the I/O interface 74 may comprise any suitable mechanism or component to at least enable a user to provide input to the operating station 7 or to provide output to the user. For example, the I/O interface 74 may comprise any suitable input mechanism, including but not limited to, a button, keypad, keyboard, click wheel, touch screen, or motion sensor. In some embodiments, the I/O interface 74 may comprise a capacitive sensing mechanism, or a multi-touch capacitive sensing mechanism (e.g., a touch screen). In some embodiments, the I/O interface 74 may comprise a visual peripheral output device for providing a display visible to the user. For example, the visual peripheral output device may comprise a screen such as, for example, a Liquid Crystal Display (LCD) screen.

In some embodiments, the communications interface 75 may comprise any suitable hardware, software, or combination of hardware and software that is capable of coupling the operating station 7 to one or more networks and/or additional devices (such as, for example, the actuator module 30, the liquid regulating module 52, and the vacuum pump 53.) The communications interface 75 may be arranged to operate with any suitable technique for controlling information signals using a desired set of communications protocols, services or operating procedures. The communications interface 75 may comprise the appropriate physical connectors to connect with a corresponding communications medium, whether wired or wireless. In some embodiments, the operating station 7 may comprise a system bus that couples various system components including the processor 71, the memory 72, the controller 73 and the I/O interface 74. The system bus can be any custom bus suitable for computing device applications.

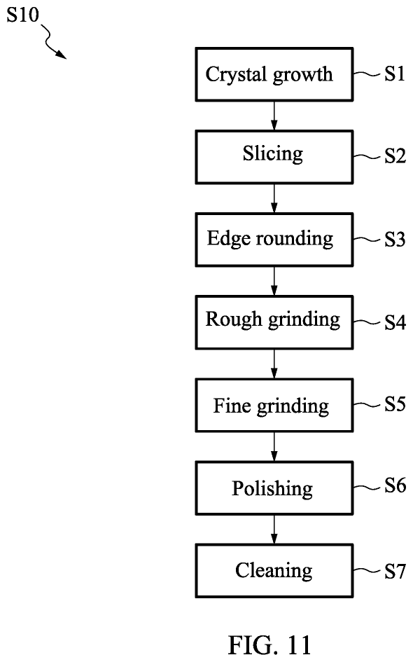

FIG. 11 is a flow chart illustrating a method S10 of fabricating ultra-thin wafers with thickness of typically less than 200 μm (e.g., 30, 50 or 100 μm), in accordance with various aspects of one or more embodiments of the present disclosure. In step S1, a crystal silicon ingot is formed by crystal growth process. In step S2, the ingot is then cut into slices of around 1 mm thickness, using an inner-diameter saw or wire saw, to form the wafers. In step S3, edge of the wafer is ground with a diamond tool to attain the required product diameter. In step S4, a rough grinding process is performed by the wafer processing system 1 of present disclosure to remove damaged surface layer. In step S5, a fine grinding process is performed by the wafer processing system 1 of present disclosure to achieve predetermined uniform thickness. In step S6, a polish process is performed by a CMP (chemical-mechanical polishing) tool to form a mirror surface by a combined mechanical and chemical action. In step S7, wafers are physically and chemically cleaned using ultra-pure water and chemicals. It is noted that, since the wafers processed by the method S10 are thinned by the rough grinding process and the fine grinding process, no, or merely a negligible, residual stress or defects is found on the surface of the wafers. The CMP process (step S6) can be directly performed once the thinning processes (steps S4 and S5) are completed. An etching process and a heat treatment process following a conventional thinning process as mentioned in the background section can be omitted in the method S10. Therefore, a processing time needed in method S10 is much less than that need in the conventional techniques.

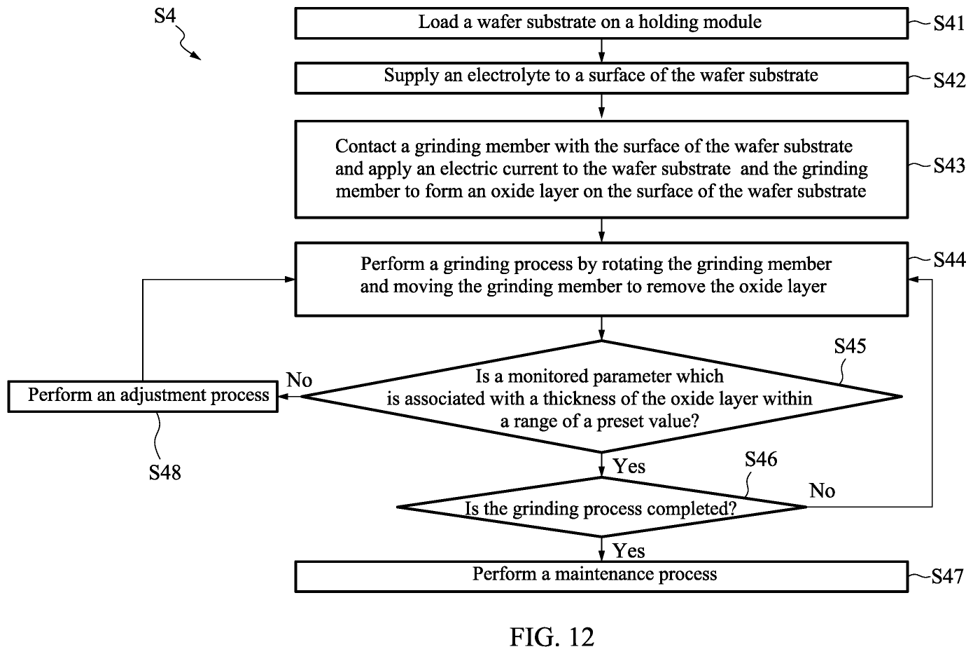

FIG. 12 is a flow chart illustrating detailed operations for a wafer thinning process, such as rough grinding process (step S4) or fine grinding process (Step S5) in method S10, in accordance with some embodiments of present disclosure. For illustration, the flow chart will be described along with the drawings shown in FIGS. 6, 8, 13 and 14. Some of the described stages can be replaced or eliminated in different embodiments.

The wafer thinning process may include step S41, in which a wafer substrate, such as wafer substrate 80, is loaded on the holding module 20. In some embodiments, when the wafer substrate 80 is loaded on the holding module 20, a vacuum force is created by the vacuum pump 53 to hold the wafer substrate 80. Since the vacuum force is evenly distributed over the entire top surface 222 of the conductive porous member 22, the wafer substrate 80 has a perfect surface flatness, after it is loaded on the holding module 20.

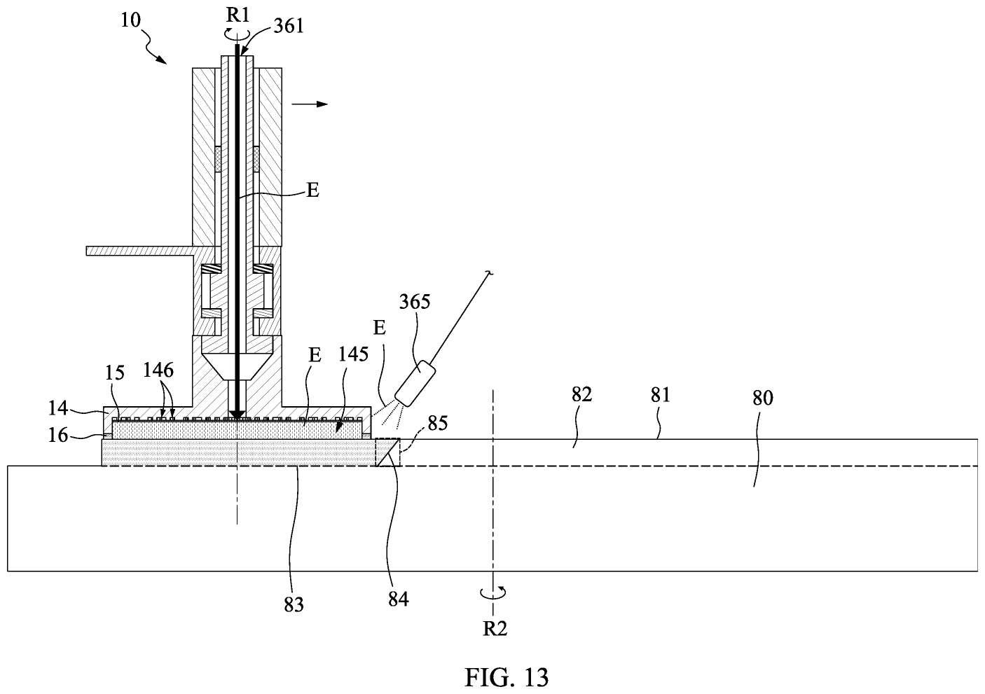

The wafer thinning process may further include step S42, in which an electrolyte is supplied to a surface of the wafer substrate 80. In some embodiments, the electrolyte may be supplied to the wafer surface through different electrolyte supply lines. For example, as shown in FIG. 13, the electrolyte is supplied to the surface 81 of the wafer substrate 80 via the electrolyte supply lines 361 and 365 simultaneously. The electrolyte E from the electrolyte supply line 361 is supplied into the recess 145, and the electrolyte E from the electrolyte supply line 365 is supplied to the surface 81 of the wafer substrate 80 which is located in a forward direction (as indicated by the arrow in FIG. 13) of the processing tool 10. The electrolyte E may be contained in the electrolyte tank 35 and then is circulated back to the electrolyte supply lines 361 and 365 through the piping unit 51. The filtration module 55 is used to remove residues in the electrolyte E in the piping unit 51 to prolong the life time of the electrolyte E.

The electrolyte E may be a solution which includes commercially available electrolytes. For example, inorganic salt based electrolytes mixed with other component. Additionally, embodiments of the disclosure contemplate using electrolyte compositions including rust inhibitors and chelating agents. In one aspect of the electrolyte solution, the electrolyte may have a temperature of 30-45° C. and a flow pressure of 35-70 KPa. The flow rate, the flow pressure, and flow volume are precisely controlled according to preset values which are determined according to empirically derived information or historic processing data.

The wafer thinning process may also include step S43, in which a grinding member 16 is moved to contact with the surface 81 of the wafer substrate 80, and an electric current is applied to the wafer substrate 80 and the grinding member 16. In some embodiments, the grinding member 16 is lowered down by the first upper actuator 31 (FIG. 2) to be in contact with the surface 81 of the wafer substrate 80. The power supply module 45 applies a direct current (DC) to the electrode 13 of the processing tool 10 (FIG. 5) and the electrode 23 of the holding module 20 (FIG. 6) to form a bias between the wafer substrate 80 and the grinding member 16. In some embodiments, a positive bias is applied to the holding module 20, and a negative bias is applied to the processing tool 10 so that the wafer substrate 80 is served as an anode and the grinding member 16 is served as a cathode. Therefore, an oxidation reaction occurs at the surface 81 of the wafer substrate 80 when the electrons flows from the wafer substrate 80 to the grinding member 16 through the electrolyte E, and an oxide layer 84 is formed on the region of the surface 81.

In general, the power supply module 45 may be a constant-voltage power supply or a constant-current power supply and is capable of providing power between about 0 Watts and 100 Watts, a voltage between about 1V and 60V, and a current between about 0 amps and about 200 amps. In addition, the power supply module 45 may apply constant current or a periodic current pulse. The frequency of the periodic current pulse is lower than 2.5 KHz. The periodic current pulse may promote the formation of oxide layer on the wafer substrate. However, the particular operating specifications of the power supply may vary according to application.

The wafer thinning process may also include step S44, in which a grinding process is performed by rotating and moving the grinding member 16 to remove the oxide layer 84 while the steps S43 and S44 last. In some embodiments, the grinding member 16 is rotated about the rotation axis R1 at a maximum rotation speed of about 5000 rpm, and the wafer substrate 80 is rotated about the rotation axis R2 at a maximum rotation speed of about 1000 rpm. The moving speed of the grinding member 16, or the processing tool 10, in the X-axis or the Y-axis direction, which is parallel to the surface 81 of the wafer substrate 80, is selected so that the amount of the material removed from the wafer substrate 80 is substantially the same as the amount of the oxide layer 84 formed on the wafer substrate 80.

In some embodiments, in a condition that the processing parameters are ideally controlled according to a preset values, the uppermost portion of a to-be-processed region 85 of the wafer substrate 80, which is located at the forward direction of the processing tool 10, may be oxidized before the grinding member 16 contacts this region, while the lower portion in the to-be-processed region 85 have not been oxidized. When the processing tool 10 moves to the to-be-processed region 85, the overall thickness of this region will be sufficient oxidized. Therefore, the grinding member 16 merely removes the oxide layer 84 through electrochemical activity. Since the hardness of the oxide layer 84 is remarkably less than that of the original material of the wafer substrate 80, the oxide layer 84 can be quickly and easily removed, and no, or merely a negligible, mechanical abrasion occurs. This advantagely leads to an extended life time of the grinding member 16, reduction in the amount of impurities in the electrolyte which may be produced during a mechanical abrasion, and successfully mitigates or avoids the generation of the residual stress and defects on the surface of the substrate wafer.

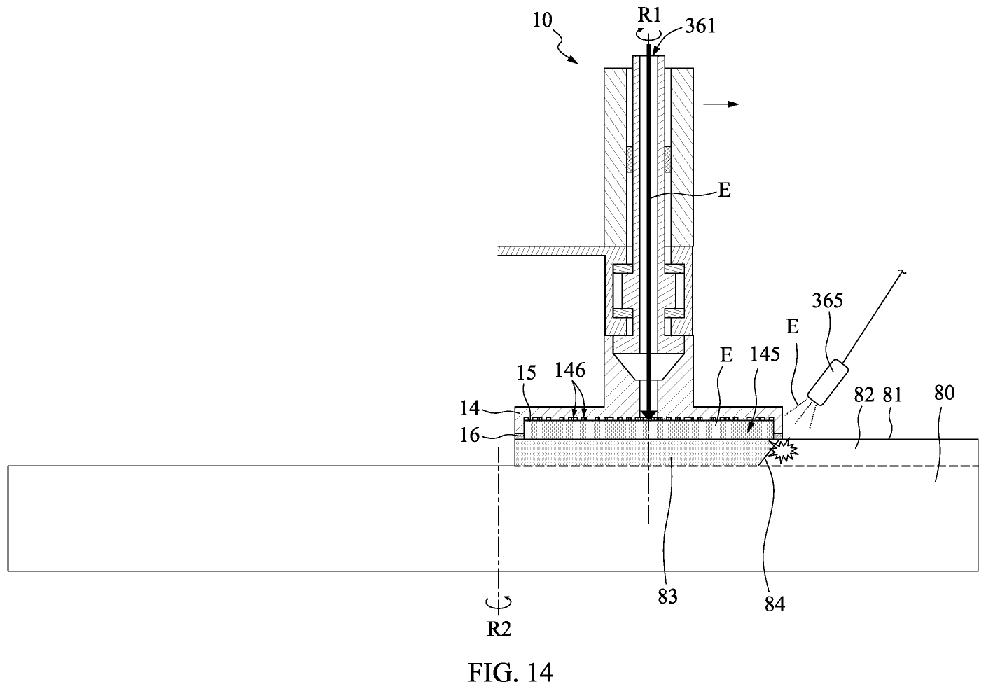

In some embodiments, as shown in FIG. 14, when abnormal occurs, the oxide layer 84 under the rotation head 14 may not be formed with desired thickness. If the thickness of the oxide layer 84 is less than that of the removal of material from the wafer substrate 80, a mechanical abrasion occurs between the grinding member 16 and the original material of the wafer substrate 80 which adversely decreases the processing quality and results in poor product yields. To address this issue, the wafer thinning process continues with step S45, in which a parameter which is associated with the thickness of the oxide layer is monitored, and the monitored parameter is compared with a preset value to determine if an abnormal occurs. If an abnormal is detected, the process continues with step S48 to conduct an adjustment process. One or more processing parameter may be modified in the adjustment process to improve the grinding quality.

Examples for controlling the system in response to the monitored parameter are provided as follows.

In some embodiments, the monitored parameter is a rotation speed of the grinding member 16. A decrease of the rotation speed of the grinding member 16 may indicate that the grinding member 16 is in contact with the non-oxidized material of the wafer substrate 80. To address this issue, the controller 73 may issue a control signal to the submerged pump 527 (FIG. 8) to increase the flow rate of the electrolyte so as to ensure the oxide layer 84 is formed with a predetermined thickness.

In some other embodiments, the monitored parameter is a pressure applied on the grinding member 16. A motor load sensor mounted on the third upper actuator 33 (FIG. 2) can be utilized to detect the pressure applied on the grinding member 16. An increase of the pressure may indicate that the grinding member 16 is in contact with the non-oxidized material of the wafer substrate 80. To address this issue, the controller 73 may issue a control signal to the submerged pump 527 (FIG. 8) to increase the flow rate of the electrolyte so as to ensure the oxide layer 84 is formed with a predetermined thickness. Alternatively, the controller 73 may issue a control signal to the first upper actuator 31 (FIG. 2) to adjust the feeding speed of the grinding member 16 in the Z-axis direction.

In still some other embodiments, the monitored parameter is an electric potential difference between the grinding member 16 and the wafer substrate 80. An increase of electric potential difference may indicate that the grinding member 16 is in contact with the non-oxidized material of the wafer substrate 80. To address this issue, the controller 73 may issue a control signal to the second upper actuator 32 (FIG. 2) to adjust the feeding speed of the grinding member 16 in the X-axis direction or in the Y-axis direction.

In still yet some other embodiments, a flow rate of the electrolyte, a conductivity of the electrolyte, or a pH value of the electrolyte is monitored by the metrology module 56. When the monitored parameter is outside a range of value, the controller 73 may pause the operation of the system, and replace the electrolyte including those in the electrolyte tank 35 and in the electrolyte handling assembly 5. Additionally or alternatively, the filtration module 55 may be replaced for a new one. After the replacement of the electrolyte, the grinding process continues.

If no abnormal detects in step S45, the process continues with step S46 to determine if the grinding process is completed. In some embodiments, the grinding member 16 is arranged to move along a preset travel path. When processor 71 detects that the grinding member 16 is moved to an end point of the preset travel path, it determines the process is completed.

The fine grinding process (step S5) may be performed according to steps S41-46 and S48 shown in FIG. 12 but with different parameters. Generally, during the rough grinding process, the formation of oxide layer on the surface of the workpiece is accelerated by increasing the voltage and increasing the temperature of the electrolyte. At the same time, by reducing the speed of the grinding member and increasing the Z-axis feed speed of the rotation disc, a large amount of material can be quickly removed from the substrate. In contrast, during the fine grinding process, the oxide layer is controlled to have a uniform thin thickness by reducing the voltage and the temperature of the electrolyte. At the same time, a dense surface is formed by increasing the rotational speed of the grinding member and reducing the Z-axis feed speed. In some embodiments, the grinding member used for the rough grinding process is different from the grinding member used for the fine grinding member, wherein a grit size of the grinding member used for the rough grinding process is greater than that used for the fine grinding process. In addition, an ultra-fine polishing can be performed after the fine grinding process, and the substrate is processed with a plastic-bonded metal grinding wheel to polish the surface of the substrate. In some embodiments, if the amount of impurities in the electrode detected in the fine grinding process exceeds a threshold, the electrode is drained through the drain piping 514 and will not be recirculated back to the electrode supply lines.

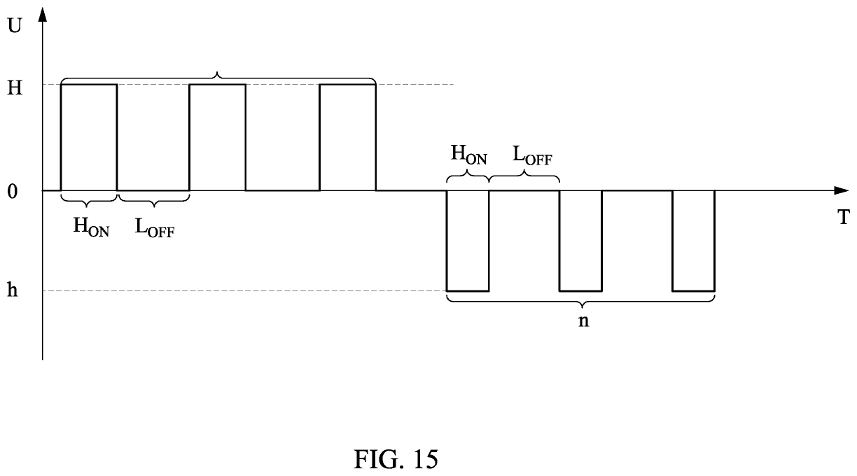

A maintenance process (step S47) may be performed after the completion of the wafer thinning process or during the wafer thinning process. In the maintenance process, the power supply module 45 applies alternate electric current to the grinding member 16 and the wafer substrate 80. FIG. 15 schematically shows the current shape of wave supplied to the wafer substrate 80. In a grinding process the power supply module 45 provides the positive output to the wafer substrate 80 to drive the oxidation reaction into the surface of the wafer substrate 80. However, after a period of time of processing, impurities may be clogged within the grinding member 16 or the hardness or sharpness of the grinding member 16 may be degraded. To clean the grinding member 16, the power supply module 45 provides the negative output to the wafer substrate 80 and provides the positive output to the grinding member 16 to drive the oxidation reaction into the grinding member 16. Additionally, the grinding member 16 is driven to rotate relative to the wafer substrate or a dummy wafer. As a result, the impurities in the grinding member 16 can be removed from the grinding member 16 and/or the grinding member 16 can be sharpened. The period of time (Hon) of generation of the positive output and the period of time (hon) of generation of the negative output is in a range of 1 to 999.9 ms. The interval (Loff) between two consecutive positive outputs and the interval (Loff) between two consecutive negative outputs is in a range of 1 to 999.9 ms. The frequency of the positive outputs may be different from that of the negative outputs. The power supply module 45 provides a voltage between about −15V to 15V.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

1. A wafer processing system comprising:
a processing tool comprising at least one grinding member configured to remove material from a wafer substrate;
at least one electrolyte supply line configured to supply an electrolyte to the wafer substrate;
a holding module positioned below the processing tool and comprising:
a conductive base, wherein at least one fluid channel extends from a top surface to a bottom surface of the conductive base;
a conductive porous member positioned on the top surface of the conductive base; and
a vacuum source fluidly communicated with the fluid channel of the conductive base to create a vacuum to hold the wafer substrate on the conductive porous member;
an actuator assembly configured to drive at least one of a rotation of the grinding member and a rotation of the conductive base; and
a power supply module configured to apply an electric current to the grinding member and to the conductive porous member through the conductive base.

2. The wafer processing system of claim 1, further comprising a fluid conveying member configured to provide a fluid communication between the fluid channel of the conductive base and the vacuum source while the conductive base is rotated.

3. The wafer processing system of claim 2, wherein the fluid conveying member comprises:
a stationary housing comprising a plurality gas outlets; and
a rotation shaft positioned in the stationary housing and rotatable with the conductive base and the conductive porous member, wherein a conduit is formed within the rotation shaft and is with one end fluidly communicated with the fluid channel of the conductive base and with the other end fluidly communicated with the gas outlets.

4. The wafer processing system of claim 1, further comprising:
an electrode arranged around a rotation axis about which the conductive base rotates; and
a plurality of electric contacts positioned between the electrode and the conductive base,
wherein the electrode is kept stationary while the conductive base is rotated, and the electric current from the power supply module is applied to the conductive base via the electrode and the electric contacts.

5. The wafer processing system of claim 1, wherein a top surface of the conductive base comprises a plurality of protrusions, and the conductive porous member comprises a plurality of grooves arranged relative to the protrusions.

6. The wafer processing system of claim 1, wherein the conductive porous member is made of material selected from the group consisting of stainless steel, titanium alloy, and tungsten carbide.

7. The wafer processing system of claim 1, further comprising:
an exhaust piping fluidly communicated with the fluid channel of the conductive base, wherein the vacuum source is connected to the exhaust piping;
an electrolyte reservoir configured to store the electrolyte;
a bypass piping fluidly communicated between the exhaust piping and the electrolyte reservoir; and
a liquid regulating module operative in an operating mode and a rest mode, wherein in the operating mode, the liquid regulating module guides the fluid from the fluid channel to an ambient via the exhaust piping, and in the rest mode, the liquid regulating module guides the fluid from the fluid channel to the electrolyte reservoir via the exhaust piping and the bypass piping.

8. The wafer processing system of claim 7, further comprising:
a supply piping fluidly communicated between the electrolyte reservoir and the at least one electrolyte supply line; and
a filtration module connected to the supply piping;
wherein the electrolyte from the electrolyte reservoir is circulated back to the at least one electrolyte supply line via the filtration module.

9. The wafer processing system of claim 1, wherein the processing tool further comprises a rotation head defining a recess at a bottom surface thereof, and the grinding member is positioned on the bottom surface of the rotation head and surrounds the recess, wherein the at least one electrolyte supply line comprises a first electrolyte supply line configured to discharge the electrolyte into the recess.

10. The wafer processing system of claim 1, wherein the at least one electrolyte supply line further comprises a second electrolyte supply line configured to discharge the electrolyte to a contact point between the grinding member and the wafer substrate.

11. A wafer processing system comprising:
a processing tool comprising:
a rotation shaft;
a rotation head fixed to a lower end of the rotation shaft and defining a recess at a bottom surface of the rotation head;
a grinding member positioned on the bottom surface of the rotation head and surrounding the recess;
a first electrode surrounding the rotation shaft and electrically connected to the rotation head; and
a fluid supply line formed within the rotation shaft and the rotation head and configured to supply an electrolyte to the recess;
a holding module configured to hold a wafer substrate and comprising a second electrode;
an actuator assembly configured to drive a rotation of the processing tool; and
a power supply module configured to apply an electric current to the first and the second electrodes.

12. The wafer processing system of claim 11, wherein the grinding member is made of material consisting conductive metallic powder and non-conductive abrasive particles.

13. The wafer processing system of claim 11, wherein the rotation head comprises:
a disc, wherein a plurality of grooves are formed at a lower surface of the disc portion, and an end of the fluid line is formed on the disc;
a flange extends downward from a peripheral edge of the disc, wherein the recess is defined by the disc and the flange; and
a fluid guiding plate having a plurality of holes formed thereon for allowing electrolyte from the fluid line passing through.

14. The wafer processing system of claim 11, wherein the recess of the rotation head is surrounded by a flange that downward extends to the bottom surface of the rotation head, and the flange comprises a plurality of notches that are fluidly communicated with the recess.

15. The wafer processing system of claim 11, further comprising a transducer connected to the fluid supply line to generate an ultrasonic energy to the electrolyte.

16. A wafer processing method, comprising:
loading a wafer substrate on a holding module;
contacting a grinding member with a surface of the wafer substrate, wherein the grinding member is arranged around a recess;
applying an electric current to the wafer substrate and the grinding member and supplying an electrolyte into the recess so as to form an oxide layer on the surface of the wafer substrate;
performing a grinding process by rotating the grinding member; and
adjusting the movement of the grinding member or the supply of the electrolyte when a monitored parameter that is associated with thickness of the oxide layer is not within a range of a preset value.

17. The method of claim 16, wherein the monitored parameter is a rotation speed of the grinding member, and when the rotation speed of the grinding member is lower than a preset value, a flow rate of the electrolyte is increased.

18. The method of claim 16, wherein the monitored parameter is a pressure applied on the grinding member, and when the pressure is greater than a preset value, a flow rate of the electrolyte is increased or a height of the grinding member relative to the wafer substrate is decreased.

19. The method of claim 16, wherein the monitored parameter is an electric potential difference between the grinding member and the wafer substrate, and when the electric potential difference is outside a range of value, a moving speed of the grinding member is changed.

20. The method of claim 16, further comprising:
stopping the grinding process when a flow rate of the electrolyte, a conductivity of the electrolyte, or a pH value of the electrolyte is outside a range of value; and
replacing the electrolyte after the grinding process is stopped.
